(19) United States
(12) Patent Application Publication
(10) Pub. No.: US 2026/0333998 A1
(43) Pub. Date: Oct. 22, 2026

(54) LIGHT-EMITTING DEVICE, DISPLAY PANEL, AND DISPLAY APPARATUS

(71) Applicant: Wuhan China Star Optoelectronics Technology Co., Ltd., Wuhan (CN)

(72) Inventor: Jixin JIANG, Wuhan (CN)

(73) Assignee: Wuhan China Star Optoelectronics Technology Co., Ltd., Wuhan (CN)

(21) Appl. No.: 19/305,918

(22) Filed: Aug. 21, 2025

Related U.S. Application Data
(63) Continuation of application No. PCT/CN2025/091797, filed on Apr. 28, 2025.

(30) Foreign Application Priority Data
Apr. 17, 2025 (CN) 202510487613.0

(51) Int. Cl. H10K 50/16; H10K 85/60; H10K 101/40; H10K 102/00

(52) U.S. Cl. CPC H10K 50/16; H10K 85/6572; H10K 2101/40; H10K 2102/351

(57) ABSTRACT

A light-emitting device, and a display panel and a display apparatus including the light-emitting device are provided. The light-emitting device includes an anode, a hole injection layer, a hole transport layer, a light-emitting layer, and an electron transport layer that are arranged sequentially. Materials of the electron transport layer include an electron transport material and an electron-type semiconductor material, and a lowest unoccupied molecular orbital energy level of the electron-type semiconductor material is higher than a lowest unoccupied molecular orbital energy level of the electron transport material.

### RELATED APPLICATIONS

This application is a Continuation of PCT Patent Application No. PCT/CN2025/091797 having International filing date of Apr. 28, 2025, which claims the benefit of priority of China Patent Application No. 202510487613.0 filed on Apr. 17, 2025. The contents of the above applications are all incorporated by reference as if fully set forth herein in their entirety.

### TECHNICAL FIELD

The present disclosure relates to the field of display, and in particular, to a light-emitting device, a display panel, and a display apparatus where a balance between electrons and holes in the light-emitting device used are maintained.

### BACKGROUND

At present, the luminous efficiency of the organic light-emitting diodes can be improved by designing light extraction structures outside the organic light-emitting diodes, or by optimizing structures of devices and improving materials of the organic light-emitting diodes. Although the development cycle of the light extraction structures is short, the overall efficiency is limited by the efficiency level of the organic light-emitting diodes themselves. The improvement of luminous efficiency of organic light-emitting diodes can effectively reduce power consumption of display panels and enhance competitiveness of products.

### SUMMARY

In a first aspect, there is a provided a light-emitting device, which includes an anode, a hole injection layer, a hole transport layer, a light-emitting layer, and an electron transport layer. The hole injection layer is disposed on a side of the anode. The hole transport layer is disposed on a side of the hole injection layer away from the anode. The light-emitting layer is disposed on a side of the hole transport layer away from the hole injection layer. The electron transport layer is disposed on a side of the light-emitting layer away from the hole transport layer. Materials of the electron transport layer include an electron transport material and an electron-type semiconductor material, and a lowest unoccupied molecular orbital energy level of the electron-type semiconductor material is higher than a lowest unoccupied molecular orbital energy level of the electron transport material.

In a second aspect, there is a provided a display panel including the light-emitting device as described above.

In a third aspect, there is a provided a display apparatus including the display panel as described above.

### BRIEF DESCRIPTION OF THE DRAWINGS

In order to explain technical solutions in embodiments of the present disclosure more clearly, the following will briefly introduce the drawings needed to be used in description of the embodiments. Apparently, the drawings in the following description are only some embodiments of the present disclosure. For ordinary skilled in the art, other drawings can be obtained from these drawings without paying creative effort.

FIG. 1 is a schematic structural diagram of a light-emitting device according to some embodiments of the present disclosure.

FIG. 2 is a schematic diagram of transport of carriers in light-emitting devices provided according to some embodiments of the present disclosure.

FIG. 3 is a distribution diagram of brightness indices of light-emitting devices according to some embodiments of the present disclosure.

FIG. 4 is a distribution diagram of current efficiency of light-emitting devices according to some embodiments of the present disclosure.

FIG. 5 is a schematic diagram of a display panel according to some embodiments of the present disclosure.

FIG. 6 is a schematic diagram of a display apparatus according to some embodiments of the present disclosure.

### DETAILED DESCRIPTION

Technical solutions in the embodiments of the present disclosure will be clearly and completely described with reference to the drawings. Apparently, the described embodiments are only part of the embodiments of the present disclosure, not all of them. According to the embodiments of the present disclosure, all other embodiments obtained by those skilled in the art without making creative efforts shall fall within the scope of protection of the present disclosure.

In the description of the present disclosure, it should be understood that, directional or positional relationships indicated by the terms “on”, “above”, “below”, and the like, are based on the directional or positional relationships shown in the drawings, which are used only for the convenience of describing the present disclosure and simplifying the description, rather than indicating or implying that a device or an element must have a specific direction, be constructed or operated in a specific direction. Therefore, the terms should not be interpreted as a limitation on the present disclosure.

In the present disclosure, reference numbers and/or reference letters can be repeated in different embodiments, such repetition is for the purposes of simplicity and clarity and does not itself indicate a relationship between various embodiments and/or arrangements discussed.

An organic light-emitting diode, a current-driven device, generally includes an anode, a hole injection layer, a hole transport layer, a light-emitting layer, an electron transport layer, an electron injection layer, and a cathode. For organic light-emitting diodes prepared by solution-based processes, such as those prepared by processes like spin-coating, blade coating, inkjet printing, and the like, the hole injection layer, the hole transport layer, and the light-emitting layer are prepared by inkjet printing, while the electron transport layer and the electron injection layer are prepared by evaporation deposition. Holes are injected into the device from the anode, electrons are injected into the cathode, and then the electrons and the holes combine in the light-emitting layer to form excitons and emit light through radiation. Therefore, the balance of carriers may directly affect the overall efficiency of the device. Since the transport of electrons occurs through hopping on the conjugated π bonds of organic molecules, and the mobility of electrons is significantly affected by the defect states of the device and materials, the hole mobility of organic materials is generally greater than the electron mobility of the organic materials. In the prior art, different hole injection materials and hole transport materials have been developed, and the thickness of the hole injection layer or the thickness of the hole transport layer is adjusted to match the balance of carriers. This approach does not solve the imbalance between electrons and holes.

Therefore, the present disclosure provides a light-emitting device, a display panel, and a display apparatus having enhanced luminous efficiency.

Some embodiments of the present disclosure provide a light-emitting device, which includes an anode, a hole injection layer, a hole transport layer, a light-emitting layer, and an electron transport layer. The hole injection layer is disposed on a side of the anode. The hole transport layer is disposed on a side of the hole injection layer away from the anode. The light-emitting layer is disposed on a side of the hole transport layer away from the hole injection layer. The electron transport layer is disposed on a side of the light-emitting layer away from the hole transport layer. Materials of the electron transport layer include an electron transport material and an electron-type semiconductor material, and a lowest unoccupied molecular orbital energy level of the electron-type semiconductor material is higher than a lowest unoccupied molecular orbital energy level of the electron transport material.

In the above embodiments of the light-emitting device, by doping the electron transport layer with the electron-type semiconductor material, the electron-type semiconductor material with a relatively high lowest unoccupied molecular orbital energy level increases the overall lowest unoccupied molecular orbital energy level of the electron transport layer, thus reducing the energy level difference between the electron transport layer and the light-emitting layer. This improves the electron mobility of the electron transport layer, so as to ensure the transport of electrons and maintain the balance between electrons and holes in the light-emitting device, thus improving the luminous efficiency of the light-emitting device.

In some embodiments of the light-emitting device, the lowest unoccupied molecular orbital energy level of the electron transport material is greater than or equal to −3 eV and less than or equal to −2.8 eV, and the lowest unoccupied molecular orbital energy level of the electron-type semiconductor material is greater than or equal to −2.7 eV and less than or equal to −2.6 eV.

In some embodiments of the light-emitting device, an energy level difference between the electron transport layer and the light-emitting layer is less than or equal to 0.3 eV and greater than or equal to 0.

In some embodiments of the light-emitting device, a volume ratio of the electron transport material to the electron-type semiconductor material is greater than or equal to 3:7 and less than or equal to 1:1.

In some embodiments of the light-emitting device, the electron-type semiconductor material includes a hydroxyquinoline-based material.

In some embodiments of the light-emitting device, the electron transport layer has an electron mobility greater than or equal to 10⁻⁷ cm²/(V·s) and less than or equal to 10⁻⁵ cm²/(V·s).

In some embodiments of the light-emitting device, the light-emitting device is a red light-emitting device, a green light-emitting device, or a blue light-emitting device.

In some embodiments of the light-emitting device, the light-emitting device further includes an electron injection layer and a cathode. The electron injection layer is disposed on a side of the electron transport layer away from the light-emitting layer. The cathode is disposed on a side of the electron injection layer away from the electron transport layer.

Some embodiments of the present disclosure further provide a display panel including a light-emitting device. The light-emitting device includes an anode, a first hole injection layer, a first hole transport layer, a first light-emitting layer, and a first electron transport layer. The first hole injection layer is disposed on a side of the anode. The first hole transport layer is disposed on a side of the first hole injection layer away from the anode. The first light-emitting layer is disposed on a side of the first hole transport layer away from the first hole injection layer. The first electron transport layer is disposed on a side of the first light-emitting layer away from the first hole transport layer. Materials of the first electron transport layer include a first electron transport material and a first electron-type semiconductor material, and a lowest unoccupied molecular orbital energy level of the first electron-type semiconductor material is higher than a lowest unoccupied molecular orbital energy level of the first electron transport material.

In some embodiments of the display panel, the lowest unoccupied molecular orbital energy level of the first electron transport material is greater than or equal to −3 eV and less than or equal to −2.8 eV, and the lowest unoccupied molecular orbital energy level of the first electron-type semiconductor material is greater than or equal to −2.7 eV and less than or equal to −2.6 eV.

In some embodiments of the display panel, an energy level difference between the first electron transport layer and the first light-emitting layer is less than or equal to 0.3 eV and greater than or equal to 0.

In some embodiments of the display panel, a volume ratio of the first electron transport material to the first electron-type semiconductor material is greater than or equal to 3:7 and less than or equal to 1:1.

In some embodiments of the display panel, the first electron-type semiconductor material includes a hydroxyquinoline-based material.

In some embodiments of the display panel, the first electron transport layer has an electron mobility greater than or equal to 10⁻⁷ cm²/(V·s) and less than or equal to 10⁻⁵ cm²/(V·s).

In some embodiments of the display panel, the light-emitting device is a red light-emitting device, and the display panel further includes a green light-emitting device and a blue light-emitting device. The green light-emitting device includes a second hole injection layer, a second hole transport layer, a second light-emitting layer, and a second electron transport layer that are arranged sequentially. Materials of the second electron transport layer include a second electron transport material and a second electron-type semiconductor material, and a lowest unoccupied molecular orbital energy level of the second electron-type semiconductor material is higher than a lowest unoccupied molecular orbital energy level of the second electron transport material. The blue light-emitting device includes a third hole injection layer, a third hole transport layer, a third light-emitting layer, and a third electron transport layer that are arranged sequentially. Materials of the third electron transport layer include a third electron transport material and a third electron-type semiconductor material, and a lowest unoccupied molecular orbital energy level of the third electron-type semiconductor material is higher than a lowest unoccupied molecular orbital energy level of the third electron transport material. A total thickness of the first hole injection layer, the first hole transport layer, and the first light-emitting layer is defined as a first thickness, a total thickness of the second hole injection layer, the second hole transport layer, and the second light-emitting layer is defined as a second thickness, a total thickness of the third hole injection layer, the third hole transport layer, and the third light-emitting layer is defined as a third thickness, the first thickness is greater than the second thickness, and the second thickness is greater than the third thickness.

In some embodiments of the display panel, a thickness of the first electron transport layer, a thickness of the second electron transport layer, and a thickness of the third electron transport layer are the same.

In some embodiments of the display panel, the light-emitting device further includes an electron injection layer and a cathode. The electron injection layer is disposed on a side of the first electron transport layer away from the first light-emitting layer. The cathode is disposed on a side of the electron injection layer away from the first electron transport layer.

Some embodiments of the present disclosure further provide a display apparatus including the display panel as described above.

Based on the above disclosure, the embodiments of the present disclosure provide the light-emitting device, the display panel, and the display apparatus. The light-emitting device includes the anode, the hole injection layer, the hole transport layer, the light-emitting layer, and the electron transport layer. The hole injection layer is disposed on a side of the anode. The hole transport layer is disposed on a side of the hole injection layer away from the anode. The light-emitting layer is disposed on a side of the hole transport layer away from the hole injection layer. The electron transport layer is disposed on a side of the light-emitting layer away from the hole transport layer. The materials of the electron transport layer include the electron transport material and the electron-type semiconductor material, and the lowest unoccupied molecular orbital energy level of the electron-type semiconductor material is higher than the lowest unoccupied molecular orbital energy level of the electron transport material.

At present, electron-type transport materials with low carrier mobility are generally used to optimize the performance of light-emitting devices. However, the electron-type transport materials with low carrier mobility are not suitable for light-emitting devices prepared by solution-based processes. Therefore, the development of electron-type transport materials with high carrier mobility and the design of structures of the devices have become the focus of the light-emitting devices prepared by the solution-based processes. For a light-emitting device prepared by evaporation deposition, the hole injection layer, the hole transport layer, the light-emitting layer, the electron transport layer, and the electron injection layer are all prepared by evaporation deposition. However, for a light-emitting device prepared by a solution-based process, the hole injection layer, the hole transport layer, and the light-emitting layer are all prepared by ink jet printing, while the electron transport layer and the electron injection layer are both prepared by evaporation deposition.

In the above embodiments of the present disclosure, by doping the electron transport layer with the electron-type semiconductor material, the electron-type semiconductor material with a relatively high lowest unoccupied molecular orbital energy level increases the overall lowest unoccupied molecular orbital energy level of the electron transport layer, so as to reduce the energy level difference between the electron transport layer and the light-emitting layer. This improves the electron mobility of the electron transport layer, so as to ensure the transport of electrons and maintain the balance between electrons and holes in the light-emitting device, thus improving the light-emitting efficiency of the light-emitting device.

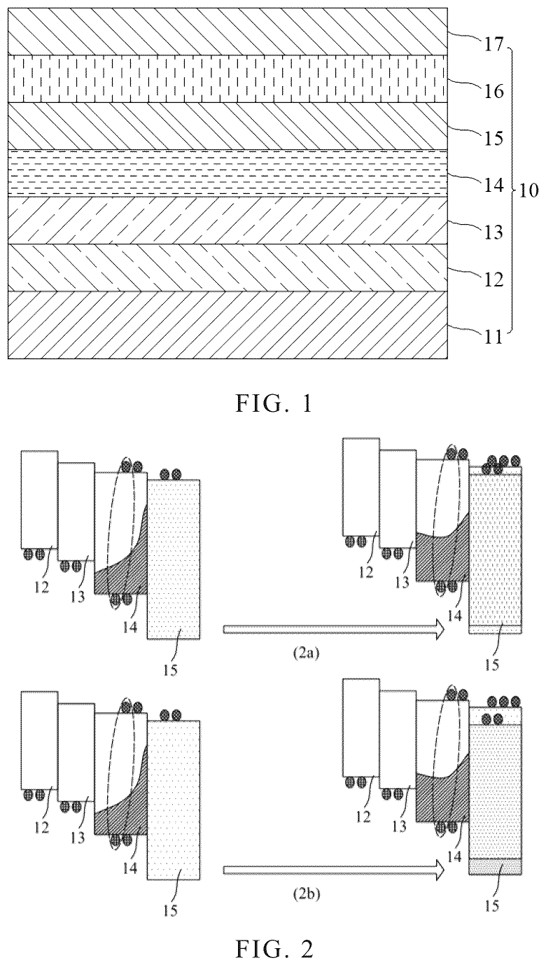

As illustrated in FIG. 1, some embodiments provide a light-emitting device 10 that includes a light-emitting layer 14, an electron transport layer 15, and a cathode 17. The electron transport layer 15 is disposed on a side of the light-emitting layer 14. The cathode 17 is disposed on a side of the electron transport layer 15 away from the light-emitting layer 14. Materials of the electron transport layer 15 include an electron transport material and an electron-type semiconductor material, and a lowest unoccupied molecular orbital (LUMO) energy level of the electron-type semiconductor material is higher than a lowest unoccupied molecular orbital energy level of the electron transport material.

In the above embodiments of the light-emitting device 10, by doping the electron transport layer 15 with the electron-type semiconductor material, the electron-type semiconductor material with a relatively high lowest unoccupied molecular orbital energy level increases the overall lowest unoccupied molecular orbital energy level of the electron transport layer 15, which improves the electron mobility of the electron transport layer 15, so as to ensure the transport of electrons and maintain the balance between electrons and holes in the light-emitting device 10, thus improving the luminous efficiency of the light-emitting device 10.

In some embodiments, as illustrated in FIG. 1, the light-emitting device 10 further includes an anode 11, a hole injection layer 12, a hole transport layer 13, and an electron injection layer 16. The anode 11 is disposed on a side of the light-emitting layer 14 away from the electron transport layer 15. The hole injection layer 12 is disposed between the anode 11 and the light-emitting layer 14. The hole transport layer 13 is disposed between the hole injection layer 12 and the light-emitting layer 14. The electron injection layer 16 is disposed between the electron transport layer 15 and the cathode 17.

In some embodiments, the hole injection layer 12, the hole transport layer 13, and the light-emitting layer 14 are all prepared by ink-jet printing, and the electron transport layer 15 and the electron injection layer 16 are both prepared by evaporation deposition.

In some embodiments, as illustrated in FIG. 1, the light-emitting device 10, an organic light-emitting diode, includes the anode 11, and the hole injection layer 12, the hole transport layer 13, the light-emitting layer 14, the electron transport layer 15, the electron injection layer 16, and the cathode 17 that are sequentially stacked on the anode 11.

In some embodiments, the structure of film layers of the light-emitting device 10 is not limited to the embodiments as described above. The light-emitting device 10 may further include at least one of a hole blocking layer, an electron blocking layer, an interface modification layer, an optical coupling layer, and the like.

In some embodiments, the anode 11 has a laminated structure that includes three layers arranged sequentially. For example, the three layers include a transparent conductive material, a metal, and a transparent conductive material, respectively. The transparent conductive material may include indium zinc oxide (IZO) or indium tin oxide (ITO). The metal may include silver.

In some embodiments, the lowest unoccupied molecular orbital energy level of the electron transport material is greater than or equal to −3 eV and less than or equal to −2.8 eV, and the lowest unoccupied molecular orbital energy level of the electron-type semiconductor material is greater than or equal to −2.7 eV and less than or equal to −2.6 eV. The electron-type semiconductor material with a relatively high lowest unoccupied molecular orbital energy level can increase the overall lowest unoccupied molecular orbital energy level of the electron transport layer 15, so as to reduce the energy level difference between the electron transport layer 15 and the light-emitting layer 14. This improves the electron mobility of the electron transport layer 15, so as to ensure the transport of electrons and maintain the balance between electrons and holes in the light-emitting device 10, thus improving the luminous efficiency of the light-emitting device 10.

In some embodiments, the lowest unoccupied molecular orbital energy level of the electron transport material is −3 eV, −2.95 eV, −2.9 eV, −2.85 eV, or −2.8 eV, and the lowest unoccupied molecular orbital energy level of the electron-type semiconductor material is −2.7 eV, −2.68 eV, −2.65 eV, −2.62 eV, or −2.6 eV.

In some embodiments, an energy level difference between the electron transport layer 15 and the light-emitting layer 14 is less than or equal to 0.3 eV and greater than or equal to 0. This can improve the electron mobility of the electron transport layer 15, so as to ensure the transport of electrons and maintain the balance between electrons and holes in the light-emitting device 10, thus improving the luminous efficiency of the light-emitting device 10. For example, the energy level difference between the electron transport layer 15 and the light-emitting layer 14 may be 0.3 eV, 0.2 eV, 0.1 eV, 0, or the like.

In some embodiments, a volume ratio of the electron transport material to the electron-type semiconductor material is greater than or equal to 3:7 and less than or equal to 1:1. For example, the volume ratio of the electron transport material to the electron-type semiconductor material may be 3:7, 2:3, 1:1, or the like.

It should be noted that, if a proportion of the electron transport material or a proportion of the electron-type semiconductor material in the electron transport layer by volume is too low, the electron mobility of the electron transport layer may decrease, resulting in a decrease in recombination efficiency of electrons and holes, which may lead to a decrease in the luminous efficiency of the light-emitting device. In addition, if the proportion of the electron transport materials is too low, it may lead to an imbalance between injection and transport of electrons, which may increase the current density and accelerate the aging process of the material, affecting the stability and service life of the light-emitting device. If the proportion of the electron-type semiconductor material is too high, not only the stability of the electron transport layer is reduced, but also the recombination efficiency of electrons and holes is reduced, resulting in a decrease in the luminous efficiency and service life of the light-emitting device. In the embodiments as described above, by limiting the volume ratio of the electron transport material to the electron-type semiconductor material to be in the range of 3:7 to 5:5, the luminous efficiency of the light-emitting device can be improved and the service life of the light-emitting device can be prolonged.

In some embodiments, a molecular structure of the electron transport material contains an electron acceptor group. The electron acceptor group may be selected from a group consisting of a triazine group, a cyano group, a carbazole group, and a nitrogen-containing heterocyclic group.

It should be noted that, for a light-emitting device prepared by a solution-based process, in the case where the transport of holes is much better than the transport of electrons, the development of electron transport materials focuses on the increase of electron acceptor groups. The electron acceptor groups are capable of capturing electrons, so as to enhance the ability of the electron transport materials to accept electrons. Therefore, in the above embodiments, since the electron acceptor group, which is selected from a group consisting of a triazine group, a cyano group, a carbazole group, and a nitrogen-containing heterocyclic group, is introduced into the molecular structure of the electron transport material, the number of free electrons in the electron transport material can be increased. This improves the concentration of carriers in the electron transport layer 15, thus increasing the electron mobility of the electron transport layer 15.

In some embodiments, the electron transport material is selected from a group consisting of 1,2,4-bis(4,6-diphenyl-1,3,5-triazin-2-yl) phenol, bis(4,6-diphenyl-2,4,6-tris(carbazol-9-yl)-1,3,5-triazine, 2,4,6-tris(3-1,3,5-triazin-2-yl) biphenyl, (cyano)phenyl)-1,3,5-triazine, derivatives of triphenylamine-cyanotriazine, and 2,4,6-tris(carbazole-9-yl)-1,3,5-triazine.

In some embodiments, the electron-type semiconductor material includes a hydroxyquinoline-based material. The hydroxyquinoline-based material has a higher lowest unoccupied molecular orbital energy level than the electron transport material. After doping, it can form molecular orbital hybridization with the electron transport material. As a strong electron acceptor, the hydroxyquinoline-based material can attract electrons from the electron transport layer 15 to form a charge transfer complex. This charge transfer effect alters the distribution of electrons in the electron transport layer 15, thus increasing the overall lowest unoccupied molecular orbital energy level of the electron transport layer 15. As a result, the energy level of the electron transport layer 15 becomes closer to the Fermi energy level of the cathode 17, and the energy level difference between the electron transport layer 15 and the light-emitting layer 14 is reduced, which can further improve the electron mobility of the electron transport layer 15.

In some embodiments, the hydroxyquinoline-based material is selected from a group consisting of lithium hydroxyquinoline, magnesium hydroxyquinoline, aluminum hydroxyquinoline, and gallium hydroxyquinoline.

In some embodiments, the electron transport layer 15 has an electron mobility greater than or equal to 10⁻⁷ cm²/(V·s) and less than or equal to 10⁻⁵ cm²/(V·s). For example, the electron transport layer 15 may have an electron mobility of 10⁻⁷ cm²/(V·s), 5×10⁻⁷ cm²/(V·s), 10⁻⁶ cm²/(V·s), 5×10⁻⁶ cm²/(V·s), 10⁻⁵ cm²/(V·s), or the like.

It should be noted that, if the electron mobility of the electron transport layer 15 is too low, the transport of electrons is relatively slow, resulting in a decrease in the luminous efficiency of the light-emitting device. If the electron mobility is too high, it may cause an imbalance in the mobility between electrons and holes and reduce the recombination probability of electrons and holes. This leads to a decrease in the luminous efficiency of the light-emitting device and affects the stability of the light-emitting device, resulting in a decrease in the life of the light-emitting device. In the above embodiments, by doping the electron transport layer 15 with the electron-type semiconductor material, the electron-type semiconductor material with a relatively high lowest unoccupied molecular orbital energy level can increase the overall lowest unoccupied molecular orbital energy level of the electron transport layer 15, thus reducing the energy level difference between the electron transport layer and the light-emitting layer. This increases the electron mobility of the electron transport layer 15 from the current range of 10⁻⁵ cm²/(V·s) to 10⁻⁴ cm²/(V·s) to a range of 10⁻⁷ cm²/(V·s) to 10⁻⁵ cm²/(V·s), so as to ensure the transport of electrons and maintain the balance between electrons and holes in the light-emitting device, thus improving the luminous efficiency of the light-emitting device.

In some embodiments, a thickness of the electron transport layer 15 and the electron mobility of the electron transport layer 15 satisfy the following equation: μ=L²/(AE), where μ represents the electron mobility of the electron transport layer 15, L represents the thickness of the electron transport layer 15, A represents a constant with a value of 0.44, and E represents the electric field strength at the electron transport layer 15. When the electric field strength remains constant, the thickness of the electron transport layer 15 is positively correlated with the electron mobility of the electron transport layer 15. Specifically, the larger the electron mobility of the electron transport layer 15, the thicker the thickness of the electron transport layer 15. Therefore, the thickness of the electron transport layer can be adjusted according to the electron mobility of the electron transport layer 15 to match the transport of holes. This can realize the balance between electrons and holes in the light-emitting device, thus improving the luminous efficiency of the light-emitting device.

In some embodiments, the light-emitting device 10 may be a red light-emitting device, a green light-emitting device, or a blue light-emitting device.

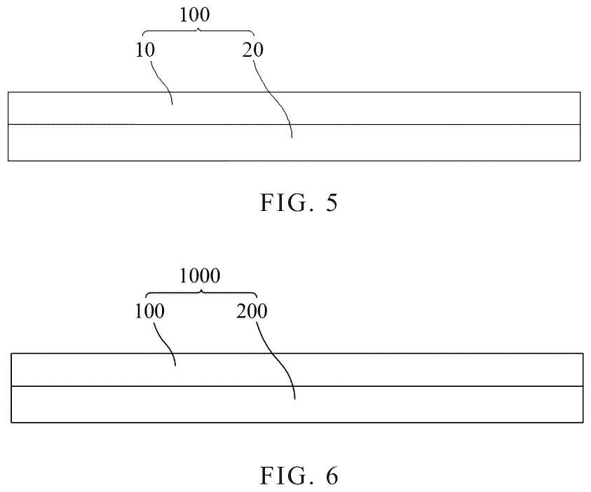

As illustrated in FIG. 5, some embodiments of the present disclosure provide a display panel 100, which includes an array substrate 20 and a light-emitting device disposed thereon. The light-emitting device may adopt the light-emitting device 10 as described in any one of the above embodiments, so as to realize the same or similar technical effects as those in the above embodiments.

In some embodiments, the array substrate 20 includes a base substrate and a driving circuit layer disposed on the substrate. The driving circuit layer may include a plurality of pixel driving circuits. The array substrate 20 may adopt the array substrate of the existing display panel to realize the same or similar functions. The display panel 100 may include a plurality of light-emitting devices arranged on the array substrate 20 in an array. Each light-emitting device is electrically connected to a corresponding pixel driving circuit, so that the light-emitting devices can emit light under the driving of the pixel driving circuits.

In some embodiments of the display panel 100, the light-emitting device may be a red light-emitting device, a green light-emitting device, or a blue light-emitting device. Taking the red light-emitting device 10 as an example, the display panel 100 may further include a green light-emitting device and a blue light-emitting device. It can be understood that the green light-emitting device and the blue light-emitting device may have the same structure as the aforementioned red light-emitting device. In some implementations, each of the green light-emitting device and the blue light-emitting device is provided with an anode, and a hole injection layer, a hole transport layer, a light-emitting layer, an electron transport layer, an electron injection layer, and a cathode that are sequentially stacked on the anode. Materials of the electron transport layer of the green light-emitting device include an electron transport material and an electron-type semiconductor material, and for the green light-emitting device, a lowest unoccupied molecular orbital level of the electron-type semiconductor material is higher than a lowest unoccupied molecular orbital level of the electron transport material. Similarly, materials of the electron transport layer of the blue light-emitting device include an electron transport material and an electron-type semiconductor material, and for the blue light-emitting device, a lowest unoccupied molecular orbital level of the electron-type semiconductor material is higher than a lowest unoccupied molecular orbital level of the electron transport material.

In some embodiments, the electron transport materials of the red, green, and blue light-emitting devices may be the same or different, and the electron-type semiconductor materials of the red, green, and blue light-emitting devices may be the same or different. When the electron transport materials of the red, green, and blue light-emitting devices are the same, and the electron-type semiconductor materials of the red, green, and blue light-emitting devices are the same either, the electron transport materials of the three light-emitting devices can be the same, and the electron-type semiconductor materials of the three light-emitting devices can be the same at the same time.

In some embodiments, a total thickness of the hole injection layer, the hole transport layer, and the light-emitting layer of the red light-emitting device is defined as a first thickness. A total thickness of the hole injection layer, the hole transport layer, and the light-emitting layer of the green light-emitting device is defined as a second thickness. A total thickness of the hole injection layer, the hole transport layer, and the light-emitting layer of the blue light-emitting device is defined as a third thickness. The first thickness is greater than the second thickness, and the second thickness is greater than the third thickness. In this way, the carrier mobility of the hole transport layers in the red, green, and blue light-emitting devices can be matched with the electron mobility of their respective electron transport layers. Additionally, the cavity length of each red, green, and blue light-emitting device can be matched with the wavelength of the corresponding color light. This ensures the transport of electrons in the electron transport layers and improves the luminous efficiency of different colors of the light-emitting devices in the display panel 100.

In some embodiments, a thickness of the hole injection layer in the red light-emitting device is different from thicknesses of the hole injection layers in the green and blue light-emitting devices. Similarly, a thickness of the hole transport layer in the red light-emitting device is different from thicknesses of the hole transport layers in the green and blue light-emitting devices, and a thickness of the light-emitting layer in the red light-emitting device is different from thicknesses of the light-emitting layers in the green and blue light-emitting devices. By adjusting the thickness of their respective hole injection layers, hole transport layers, and light-emitting layers, the first thickness is made greater than the second thickness, and the second thickness is greater than the third thickness. In this way, the carrier mobility of the hole transport layers in the red, green, and blue light-emitting devices can be matched with the electron mobility of their respective electron transport layers. Additionally, the cavity length of each red, green, and blue light-emitting device can be matched with the wavelength of the corresponding color light. This ensures the transport of electrons in the electron transport layers and improves the luminous efficiency of different colors of the light-emitting devices in the display panel 100.

In some embodiments, a thickness of the electron transport layer in the red light-emitting device is the same as thicknesses of the electron transport layers in the green and blue light-emitting devices. Additionally, a volume ratio of the electron transport material to the electron-type semiconductor material in the electron transport layer of the red light-emitting device is the same as those in the green and blue light-emitting devices. Therefore, there is no need for differential design in the thicknesses of the electron transport layers or the volume ratios of the electron transport materials to the electron-type semiconductor materials among the red, green, and blue light-emitting devices. Instead, it is only necessary to adjust the thicknesses of the hole injection layer, the hole transport layer, and the light-emitting layer prepared by inkjet printing to match the electron mobility of the electron transport layer. This approach improves the luminous efficiency of the light-emitting devices without increasing the process complexity of the display panel.

The present disclosure provides Examples 1 to 6 and Comparative Example 1 to illustrate the light-emitting devices as described above.

In Example 1, a blue light-emitting device is provided and includes an anode, and a hole injection layer, a hole transport layer, a light-emitting layer, an electron transport layer, an electron injection layer, and a cathode that are sequentially stacked on the anode. Materials of the electron transport layer include an electron transport material and an electron-type semiconductor material. The electron transport material is 1,2,4-bis(4,6-diphenyl-1,3,5-triazin-2-yl) phenol, and the electron-type semiconductor material is lithium hydroxyquinoline. A volume ratio of the electron transport material to the electron-type semiconductor material is 1:1. The electron transport layer has a thickness of 30 nanometers.

In Example 2, a blue light-emitting device is provided and includes an anode, and a hole injection layer, a hole transport layer, a light-emitting layer, an electron transport layer, an electron injection layer, and a cathode that are sequentially stacked on the anode. Materials of the electron transport layer include an electron transport material and an electron-type semiconductor material. The electron transport material is 1,2,4-bis(4,6-diphenyl-1,3,5-triazin-2-yl) phenol, and the electron-type semiconductor material is lithium hydroxyquinoline. A volume ratio of the electron transport material to the electron-type semiconductor material is 2:3. The electron transport layer has a thickness of 30 nanometers.

In Example 3, a blue light-emitting device is provided and includes an anode, and a hole injection layer, a hole transport layer, a light-emitting layer, an electron transport layer, an electron injection layer, and a cathode that are sequentially stacked on the anode. Materials of the electron transport layer include an electron transport material and an electron-type semiconductor material. The electron transport material is 1,2,4-bis(4,6-diphenyl-1,3,5-triazin-2-yl) phenol, and the electron-type semiconductor material is lithium hydroxyquinoline. A volume ratio of the electron transport material to the electron-type semiconductor material is 3:7. The electron transport layer has a thickness of 30 nanometers.

In Example 4, a green light-emitting device is provided and includes an anode, and a hole injection layer, a hole transport layer, a light-emitting layer, an electron transport layer, an electron injection layer, and a cathode that are sequentially stacked on the anode. Materials of the electron transport layer include an electron transport material and an electron-type semiconductor material. The electron transport material is 1,2,4-bis(4,6-diphenyl-1,3,5-triazin-2-yl) phenol, and the electron-type semiconductor material is lithium hydroxyquinoline. A volume ratio of the electron transport material to the electron-type semiconductor material is 1:1. The electron transport layer has a thickness of 25 nanometers.

In Example 5, a green light-emitting device is provided and includes an anode, and a hole injection layer, a hole transport layer, a light-emitting layer, an electron transport layer, an electron injection layer, and a cathode that are sequentially stacked on the anode. Materials of the electron transport layer include an electron transport material and an electron-type semiconductor material. The electron transport material is 1,2,4-bis(4,6-diphenyl-1,3,5-triazin-2-yl) phenol, and the electron-type semiconductor material is lithium hydroxyquinoline. A volume ratio of the electron transport material to the electron-type semiconductor material is 1:1. The electron transport layer has a thickness of 30 nanometers.

In Example 6, a green light-emitting device is provided and includes an anode, and a hole injection layer, a hole transport layer, a light-emitting layer, an electron transport layer, an electron injection layer, and a cathode that are sequentially stacked on the anode. Materials of the electron transport layer include an electron transport material and an electron-type semiconductor material. The electron transport material is 1,2,4-bis(4,6-diphenyl-1,3,6-triazin-2-yl) phenol, and the electron-type semiconductor material is lithium hydroxyquinoline. A volume ratio of the electron transport material to the electron-type semiconductor material is 1:1. The electron transport layer has a thickness of 40 nanometers.

In Comparative Example 1, a blue light-emitting device is provided and includes an anode, and a hole injection layer, a hole transport layer, a light-emitting layer, an electron transport layer, an electron injection layer, and a cathode that are sequentially stacked on the anode. Materials of the electron transport layer include an electron transport material and an electron-type semiconductor material. The electron transport material is poly(p-phenylene vinylene), and the electron-type semiconductor material is lithium hydroxyquinoline. The electron transport layer has a thickness of 30 nanometers.

TABLE 1

| | | Volume ratio of | | |
|---|---|---|---|---|
| | | the electron | | |
| | | transport | Thickness | |
| | | material to the | of the | |
| | Type of light- | electron-type | electron | |
| | emitting | semiconductor | transport | Brightness |
| Number | devices | material | layer/nm | index (Bi) |
| Example 1 | Blue light- | 1:1 | 30 | 163 |
| | emitting device | | | |
| Example 2 | Blue light- | 2:3 | 30 | 169 |
| | emitting device | | | |
| Example 3 | Blue light- | 3:7 | 30 | 154 |
| | emitting device | | | |
| Comparative | Blue light- | 1:1 | 30 | 140 |
| example 1 | emitting device | | | |

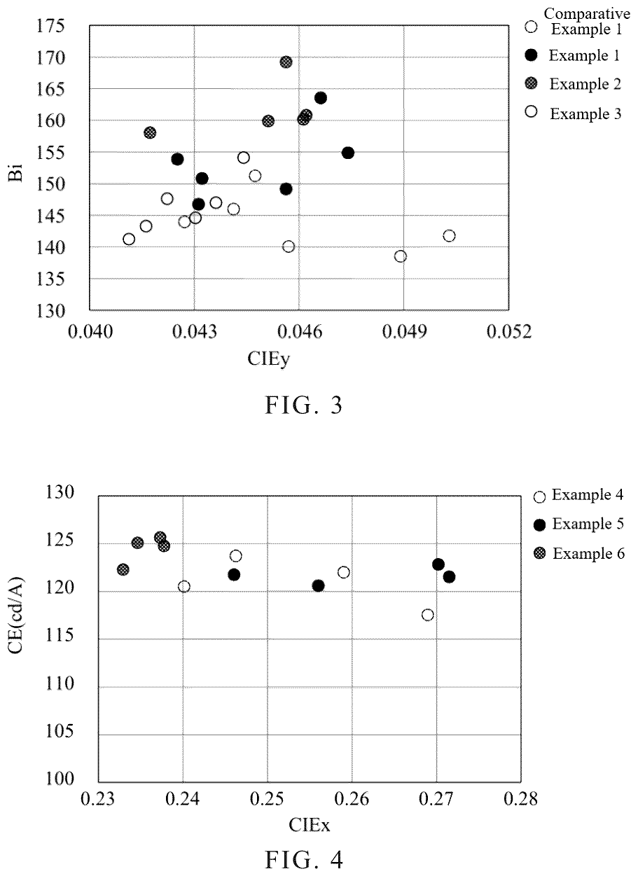

Referring to Table 1 and FIG. 3. Table 1 shows brightness indices (Bi) of blue light-emitting devices in Examples 1 to 3 and Comparative Example 1 at different volume ratios of the electron transport material to the electron-type semiconductor material. FIG. 3 is a distribution diagram of the brightness indices with color coordinates (CIEy, y-axis component in color coordinates) for the blue light-emitting devices provided in Examples 1 to 3 and Comparative Example 1. The brightness index can evaluate the luminous intensity of the light-emitting device under a specific current or voltage. Specifically, under the same current, the higher the brightness index, the higher the luminous efficiency. As can be seen from Table 1 and FIG. 3, the blue light-emitting device of Comparative Example 1 does not adopt the electron transport material containing the electron acceptor group (1,2,4-bis(4,6-diphenyl-1,3,6-triazin-2-yl) phenol) as used in Examples 1 to 3, and thus the brightness index of Comparative Example 1 is the lowest. The brightness indices of the blue light-emitting devices in Examples 1 to 3 are significantly improved compared with the brightness index of the blue light-emitting device in Comparative Example 1. Therefore, the above results of Examples 1 to 3 and Comparative Example 1 indicate that, the luminous efficiency of the light-emitting device using the electron transport material containing the electron acceptor group in the Examples of the present disclosure can be significantly improved.

Referring to Table 1 and FIG. 2. FIG. 2 is a schematic diagram of transport of carriers in the blue light-emitting devices of Comparative Example 1 and Example 1. Specifically, (2a) of FIG. 2 illustrates the blue light-emitting device provided in Comparative Example 1, and (2b) of FIG. 2 illustrates the blue light-emitting device provided in Example 1. In the blue light-emitting device provided in Comparative Example 1, the transport of holes is better than the transport of electrons. As a result, the light-emitting region is closer to the electron transport layer, leading to relatively low luminous efficiency of the blue light-emitting device. In the blue light-emitting device provided in Example 1, by doping the electron-type semiconductor material to modify the lowest unoccupied molecular orbital energy level of the electron transport layer, the light-emitting region of the blue light-emitting device is expanded, and thus the luminous efficiency is enhanced. In addition, the electron mobility of the electron transport material in the blue light-emitting device of Example 1 is higher than the electron mobility of the electron transport material in the blue light-emitting device of Comparative Example 1. Therefore, after doping the electron transport layer in the blue light-emitting device of Example 1 with the electron-type semiconductor material, the luminous efficacy of the blue light-emitting device is significantly improved due to the balance between electrons and holes in the electron transport layer.

TABLE 2

| | | Volume ratio of | | |
|---|---|---|---|---|
| | | the electron | | |
| | | transport | Thickness | |
| | | material to the | of the | Current |
| | Type of light- | electron-type | electron | efficiency |
| | emitting | semiconductor | transport | CE/ |
| Number | devices | material | layer/nm | (cd/A) |
| Example 4 | Green light- | 2:3 | 25 | 117 |
| | emitting device | | | |
| Example 5 | Green light- | 2:3 | 30 | 122 |
| | emitting device | | | |
| Example 6 | Green light- | 2:3 | 40 | 125 |
| | emitting device | | | |

Referring to Table 2 and FIG. 4. Table 2 shows current efficiency (CE) of green light-emitting devices provided in Examples 4 to 6 at different thicknesses of electron transport layers. FIG. 4 is a distribution diagram of the current efficiency with color coordinates (CIEx, x-axis component in color coordinates) for the green light-emitting devices provided in Examples 4 to 6. In Table 2, current efficiency refers to the luminous intensity of the green light-emitting device per unit current. It serves as a metric for evaluating the luminous efficacy of the green light-emitting device. Under a condition that the volume ratio of the electron transport material to the electron-type semiconductor material remains constant, the current efficiency of the green light-emitting device can be adjusted by changing the thickness of the electron transport layer. According to the results of Examples 4 to 6, the green light-emitting device has a higher luminous efficiency when the thickness of the electron transport layer is 40 nanometers than when the thickness of the electron transport layer is 25 nanometers and 30 nanometers, respectively.

In view of the above, in practical applications, the optimal luminous efficiency of the light-emitting device can be obtained by adjusting the thickness of the electron transport layer and the volume ratio of the electron transport material to the electron-type semiconductor material in the electron transport layer. The thicknesses of the electron transport layers corresponding to the optimal luminous efficiency of the light-emitting devices of different colors may be the same or different. The volume ratios of the electron transport material to the electron-type semiconductor material in the electron transport layers corresponding to the optimal luminous efficiency of the light-emitting devices of different colors may be the same or different. Both the thickness of the electron transport layer and the volume ratio of the electron transport material to the electron-type semiconductor material in the electron transport layer can be set according to actual requirements, as long as they fall within the ranges of the above parameters provided in the embodiments of the present disclosure.

As illustrated in FIG. 6, some embodiments of the present disclosure further provide a display apparatus 1000, which includes a housing 200 and a display panel disposed thereon. The display panel may adopt the display panel 100 as described in any one of the above embodiments. The display apparatus 1000 can realize the same technical effect as the display panel 100 as described in any one of the above embodiments, and will not be repeated here.

Beneficial effects of the embodiments of the present disclosure are as follows. The embodiments of the present disclosure provide the light-emitting device, the display panel, and the display apparatus. The light-emitting device includes the anode, the hole injection layer, the hole transport layer, the light-emitting layer, and the electron transport layer. The electron transport layer is disposed on a side of the light-emitting layer away from the hole transport layer. The materials of the electron transport layer include the electron transport material and the electron-type semiconductor material, and the lowest unoccupied molecular orbital energy level of the electron-type semiconductor material is higher than the lowest unoccupied molecular orbital energy level of the electron transport material. By doping the electron transport layer with the electron-type semiconductor material, the electron-type semiconductor material with a relatively high lowest unoccupied molecular orbital energy level increases the overall lowest unoccupied molecular orbital energy level of the electron transport layer, thus reducing the energy level difference between the electron transport layer and the light-emitting layer. This can improve the electron mobility of the electron transport layer, so as to ensure the transport of electrons and maintain the balance between electrons and holes in the light-emitting device, thus improving the luminous efficiency of the light-emitting device.

In the description of the present disclosure, the terms “first” and “second” are used merely for descriptive purposes and should not be construed as indicating or implying relative importance, nor as implicitly specifying the quantity of the technical features indicated. Therefore, the features limited by “first” and “second” may explicitly or implicitly include one or more features. In the description of the present disclosure, the term “a plurality of” refers to two or more than two, unless otherwise specified.

In the above embodiments, the description of each of the embodiments has its own emphasis, and for parts not described in detail in a certain embodiments, please refer to the relevant description of other embodiments.

The embodiments, examples, implementations, and related technical features of the present disclosure can be combined and replaced with each other without conflict.

The above are merely preferred embodiments of the present disclosure, and do not limit the present disclosure in any form. Any simple modifications, equivalent changes, and modifications made to the above embodiments according to the technical essence of the present disclosure without departing from the contents of the technical solutions of the present disclosure still fall within the scope of the technical solutions of the present disclosure.

What is claimed is:

1. A light-emitting device, comprising:
an anode;
a hole injection layer disposed on a side of the anode;
a hole transport layer disposed on a side of the hole injection layer away from the anode;
a light-emitting layer disposed on a side of the hole transport layer away from the hole injection layer; and
an electron transport layer disposed on a side of the light-emitting layer away from the hole transport layer;
wherein materials of the electron transport layer comprise an electron transport material and an electron-type semiconductor material, and a lowest unoccupied molecular orbital energy level of the electron-type semiconductor material is higher than a lowest unoccupied molecular orbital energy level of the electron transport material.

2. The light-emitting device of claim 1, wherein the lowest unoccupied molecular orbital energy level of the electron transport material is greater than or equal to −3 eV and less than or equal to −2.8 eV, and the lowest unoccupied molecular orbital energy level of the electron-type semiconductor material is greater than or equal to −2.7 eV and less than or equal to −2.6 eV.

3. The light-emitting device of claim 1, wherein an energy level difference between the electron transport layer and the light-emitting layer is less than or equal to 0.3 eV and greater than or equal to 0.

4. The light-emitting device of claim 1, wherein a volume ratio of the electron transport material to the electron-type semiconductor material is greater than or equal to 3:7 and less than or equal to 1:1.

5. The light-emitting device of claim 1, wherein the electron-type semiconductor material comprises a hydroxyquinoline-based material.

6. The light-emitting device of claim 5, wherein the hydroxyquinoline-based material is selected from a group consisting of lithium hydroxyquinoline, magnesium hydroxyquinoline, aluminum hydroxyquinoline, and gallium hydroxyquinoline.

7. The light-emitting device of claim 1, wherein the electron transport material is selected from a group consisting of 1,2,4-bis(4,6-diphenyl-1,3,5-triazin-2-yl) phenol, bis(4,6-diphenyl-1,3,5-triazin-2-yl) biphenyl, 2,4,6-tris(carbazol-9-yl)-1,3,5-triazine, 2,4,6-tris(3-(cyano)phenyl)-1,3,5-triazine, derivatives of triphenylamine-cyanotriazine, and 2,4,6-tris(carbazole-9-yl)-1,3,5-triazine.

8. The light-emitting device of claim 1, wherein the electron transport layer has an electron mobility greater than or equal to 10⁻⁷ cm²/(V·s) and less than or equal to 10⁻⁵ cm²/(V·s).

9. The light-emitting device of claim 1, wherein the light-emitting device is a red light-emitting device, a green light-emitting device, or a blue light-emitting device.

10. The light-emitting device of claim 1, further comprising:
an electron injection layer disposed on a side of the electron transport layer away from the light-emitting layer; and
a cathode disposed on a side of the electron injection layer away from the electron transport layer.

11. A display panel comprising a light-emitting device, wherein the light-emitting device comprises:
an anode;
a first hole injection layer disposed on a side of the anode;
a first hole transport layer disposed on a side of the first hole injection layer away from the anode;
a first light-emitting layer disposed on a side of the first hole transport layer away from the first hole injection layer; and
a first electron transport layer disposed on a side of the first light-emitting layer away from the first hole transport layer;
wherein materials of the first electron transport layer comprise a first electron transport material and a first electron-type semiconductor material, and a lowest unoccupied molecular orbital energy level of the first electron-type semiconductor material is higher than a lowest unoccupied molecular orbital energy level of the first electron transport material.

12. The display panel of claim 11, wherein the lowest unoccupied molecular orbital energy level of the first electron transport material is greater than or equal to −3 eV and less than or equal to −2.8 eV, and the lowest unoccupied molecular orbital energy level of the first electron-type semiconductor material is greater than or equal to −2.7 eV and less than or equal to −2.6 eV.

13. The display panel of claim 11, wherein an energy level difference between the first electron transport layer and the first light-emitting layer is less than or equal to 0.3 eV and greater than or equal to 0.

14. The display panel of claim 11, wherein a volume ratio of the first electron transport material to the first electron-type semiconductor material is greater than or equal to 3:7 and less than or equal to 1:1.

15. The display panel of claim 11, wherein the first electron-type semiconductor material comprises a hydroxyquinoline-based material.

16. The display panel of claim 11, wherein the first electron transport layer has an electron mobility greater than or equal to 10⁻⁷ cm²/(V·s) and less than or equal to 10⁻⁵ cm²/(V·s).

17. The display panel of claim 11, wherein the light-emitting device is a red light-emitting device, wherein the display panel further comprises:
a green light-emitting device comprising a second hole injection layer, a second hole transport layer, a second light-emitting layer, and a second electron transport layer arranged sequentially, wherein materials of the second electron transport layer comprise a second electron transport material and a second electron-type semiconductor material, and a lowest unoccupied molecular orbital energy level of the second electron-type semiconductor material is higher than a lowest unoccupied molecular orbital energy level of the second electron transport material; and
a blue light-emitting device comprising a third hole injection layer, a third hole transport layer, a third light-emitting layer, and a third electron transport layer arranged sequentially, wherein materials of the third electron transport layer comprise a third electron transport material and a third electron-type semiconductor material, and a lowest unoccupied molecular orbital energy level of the third electron-type semiconductor material is higher than a lowest unoccupied molecular orbital energy level of the third electron transport material;
wherein a total thickness of the first hole injection layer, the first hole transport layer, and the first light-emitting layer is defined as a first thickness, a total thickness of the second hole injection layer, the second hole transport layer, and the second light-emitting layer is defined as a second thickness, a total thickness of the third hole injection layer, the third hole transport layer, and the third light-emitting layer is defined as a third thickness, the first thickness is greater than the second thickness, and the second thickness is greater than the third thickness.

18. The display panel of claim 17, wherein a thickness of the first electron transport layer, a thickness of the second electron transport layer, and a thickness of the third electron transport layer are the same.

19. The display panel of claim 11, wherein the light-emitting device further comprises:
an electron injection layer disposed on a side of the first electron transport layer away from the first light-emitting layer; and
a cathode disposed on a side of the electron injection layer away from the first electron transport layer.

20. A display apparatus comprising a display panel, wherein the display panel comprises a light-emitting device comprising:
an anode;
a first hole injection layer disposed on a side of the anode;
a first hole transport layer disposed on a side of the first hole injection layer away from the anode;
a first light-emitting layer disposed on a side of the first hole transport layer away from the first hole injection layer; and
a first electron transport layer disposed on a side of the first light-emitting layer away from the first hole transport layer;
wherein materials of the first electron transport layer comprise a first electron transport material and a first electron-type semiconductor material, and a lowest unoccupied molecular orbital energy level of the first electron-type semiconductor material is higher than a lowest unoccupied molecular orbital energy level of the first electron transport material.
